(19) United States
(12) Patent Application Publication
(10) Pub. No.: US 2010/0167512 A1
(43) Pub. Date: Jul. 1, 2010

(54) Methods for Nanostructure Doping

(75) Inventors: Yaoling Pan, East Windsor, NJ (US); Jian Chen, Sunnyvale, CA (US); Francisco Leon, Palo Alto, CA (US); Shahriar Mostarshed, San Mateo, CA (US); Linda T. Romano, Sunnyvale, CA (US); Vijendra Sahi, Menlo Park, CA (US); David P. Stumbo, Belmont, CA (US)

Correspondence Address: NANOSYS INC., 2625 HANOVER ST., PALO ALTO, CA, 94304, US

(73) Assignee: NANOSYS, INC., Palo Alto, CA (US)

(21) Appl. No.: 12/720,125

(22) Filed: Mar. 9, 2010

Related U.S. Application Data
(62) Division of application No. 11/523,098, filed on Sep. 19, 2006.
(60) Provisional application No. 60/719,576, filed on Sep. 23, 2005.

(51) Int. Cl. H01L 21/22

(52) U.S. Cl. 438/549; 257/E21.135; 977/762

(57) ABSTRACT

Methods of doping nanostructures, such as nanowires, are disclosed. The methods provide a variety of approaches for improving existing methods of doping nanostructures. The embodiments include the use of a sacrificial layer to promote uniform dopant distribution within a nanostructure during post-nanostructure synthesis doping. In another embodiment, a high temperature environment is used to anneal nanostructure damage when high energy ion implantation is used. In another embodiment rapid thermal annealing is used to drive dopants from a dopant layer on a nanostructure into the nanostructure. In another embodiment a method for doping nanowires on a plastic substrate is provided that includes depositing a dielectric stack on a plastic substrate to protect the plastic substrate from damage during the doping process. An embodiment is also provided that includes selectively using high concentrations of dopant materials at various times in synthesizing nanostructures to realize novel crystallographic structures within the resulting nanostructure.

### CROSS REFERENCE TO RELATED APPLICATIONS

This application is a divisional of U.S. Ser. No. 11/523,098, filed Sep. 19, 2006, which application claims the benefit of priority of U.S. Provisional Patent Application No. 60/719,576, filed Sep. 23, 2005, each of which is hereby incorporated by reference in its entirety.

### BACKGROUND OF THE INVENTION

1. Field of the Invention

The invention relates to nanostructures, and more particularly to doping of nanostructures.

2. Background Art

Effective doping of nanostructures is a critical process in the creation of electronic devices based on nanostructures. For example, doping to create a nanostructure contact impacts the contact resistance. Similarly, channel doping impacts the device threshold and the on/off ratios. As a result, controlling the doping concentrations in nanostructures is important to achieving desirable device performance.

Existing doping techniques used in traditional semiconductor processes have limited applicability to nanostructure doping. While known traditional semiconductor doping processes such as, for example, thermal diffusion (gas, solid and liquid phase), ion implantation, and in-situ doping can be used for nanostructure doping, they are limited in terms of uniformity, conformality, and doping concentration control. For example, thermal diffusion could be useful for uniform and conformal doping to nanostructures, but the control of doping concentration, especially at the low level concentrations (e.g., 10¹⁹/cm³) is very difficult due to the saturated surface concentrations, which are normally greater than about 10²⁰/cm³) and the limited volume of the nanowire.

The use of ion implantation to dope nanostructures, on the other hand, has very good controllability of the doping concentrations. However, because of the characteristics of its beam line, it is very hard to achieve conformal doping to the nanostructures. Since it is preferred that the doping process be done on the nanostructure growth wafer, it is almost impossible to have a uniform and conformal doping of the wires using ion implantation.

The use of in situ doping to dope nanostructures has the advantages of process simplicity and uniform doping. Because of the interaction between precursors for wire growth and doping elements, the process control needed to create good crystal structures and achieve the desired doping level controls can be very difficult, especially when multiple wafers are processed at the same time.

What are needed are methods to effectively dope nanostructures that address the shortcomings of the above approaches.

### BRIEF SUMMARY OF THE INVENTION

Methods of doping nanostructures, such as nanowires, are disclosed. In one embodiment a method for doping nanostructures includes cleaning a nanostructure, coating the nanostructure with a sacrificial layer and depositing a dopant on a surface of the sacrificial layer. The dopant is then forced through the sacrificial layer into the nanostructure. The sacrificial layer is then removed and the dopant is further forced into the nanostructure.

In another embodiment a method for doping nanostructures includes heating a growth wafer containing nanostructures to a temperature and using ion implantation to implant ion dopants into the nanostructure. The temperature is sufficiently high that damage caused by ion implantation is annealed out during the implantation. The dopants are activated by further annealing the nanostructure once the ion dopants are implanted.

In another embodiment a method for doping nanostructures is provided that includes forming a dopant layer on the surface of a nanostructure and using rapid thermal annealing to drive dopants from the dopant layer into the nanostructure. The excess dopants are then stripped from the surface of the nanostructure.

In another embodiment a method for doping nanostructures on a plastic substrate is provided that includes depositing a dielectric stack on a plastic substrate, then depositing nanostructures on top of the dielectric stack. Dopants are then deposited on the nanostructures. The dopants are then laser annealed into the nanostructure. The dielectric stack reflects the laser energy to prevent damage to the plastic substrate.

In another embodiment a method for synthesizing a nanowire with electric contacts is provided that includes initiating nanowire growth with a high concentration of dopant present, such that an end portion of the nanowire will exhibit metallic characteristics. The amount of dopant concentration is reduced for a period of time, such that a middle portion of the nanowire will exhibit semiconductor characteristics. The amount of dopant is then increased, such that a second end portion of the nanowire will exhibit metallic characteristics.

Further embodiments, features, and advantages of the invention, as well as the structure and operation of the various embodiments of the invention are described in detail below with reference to accompanying drawings.

### BRIEF DESCRIPTION OF THE FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1A is a diagram of a single crystal semiconductor nanowire.

FIG. 1B is a diagram of a nanowire doped according to a core-shell structure.

FIG. 2 is a flowchart of a method for doping nanostructures, according to an embodiment of the invention.

FIG. 3 is a chart of doping concentrations in nanowires with a 2 nm sacrificial layer under different pre-diffusion conditions, according to an embodiment of the invention.

FIG. 4 is a chart of doping concentration in nanowires with a 5 nm SiO₂ sacrificial layer under different pre-diffusion conditions, according to an embodiment of the invention.

FIG. 5 is a flowchart of a method for doping nanostructures using a high energy ion implanter, according to an embodiment of the invention.

FIG. 6 is a simulation chart showing boron dopant distribution into silicon nanowires, according to an embodiment of the invention.

FIG. 7 is a flowchart of a method for controlled doping of nanostructures using a dopant coating on the nanostructures, according to an embodiment of the invention.

FIG. 8 is a flowchart of a method for doping nanostructures on a plastic substrate without damaging the plastic substrate, according to an embodiment of the invention.

FIG. 9 is a flowchart of a method for doping nanostructures using high concentrations of dopants at selected times, according to an embodiment of the invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

It should be appreciated that the particular implementations shown and described herein are examples of the invention and are not intended to otherwise limit the scope of the present invention in any way. Indeed, for the sake of brevity, conventional electronics, manufacturing, semiconductor devices, and nanowire (NW), nanorod, nanotube, and nanoribbon technologies and other functional aspects of the systems (and components of the individual operating components of the systems) may not be described in detail herein. Furthermore, for purposes of brevity, the invention is frequently described herein as pertaining to nanowires, and to a semiconductor diode device.

Moreover, while a single nanowire is illustrated for the specific implementations discussed, the implementations are not intended to be limiting and a wide range of the number of nanowires and spacing can also be used. It should be appreciated that although nanowires are frequently referred to, the techniques described herein are also applicable to other nanostructures, such as nanorods, nanotubes, nanotetrapods, nanoribbons and/or combination thereof. It should further be appreciated that the manufacturing techniques described herein could be used to create any semiconductor device type, and other electronic component types. Further, the techniques would be suitable for application in electrical systems, optical systems, consumer electronics, industrial electronics, wireless systems, space applications, or any other application.

As used herein, an “aspect ratio” is the length of a first axis of a nanostructure divided by the average of the lengths of the second and third axes of the nanostructure, where the second and third axes are the two axes whose lengths are most nearly equal to each other. For example, the aspect ratio for a perfect rod would be the length of its long axis divided by the diameter of a cross-section perpendicular to (normal to) the long axis.

The term “heterostructure” when used with reference to nanostructures refers to nanostructures characterized by at least two different and/or distinguishable material types. Typically, one region of the nanostructure comprises a first material type, while a second region of the nanostructure comprises a second material type. In certain embodiments, the nanostructure comprises a core of a first material and at least one shell of a second (or third etc.) material, where the different material types are distributed radially about the long axis of a nanowire, a long axis of an arm of a branched nanocrystal, or the center of a nanocrystal, for example. A shell need not completely cover the adjacent materials to be considered a shell or for the nanostructure to be considered a heterostructure; for example, a nanocrystal characterized by a core of one material covered with small islands of a second material is a heterostructure. In other embodiments, the different material types are distributed at different locations within the nanostructure; e.g., along the major (long) axis of a nanowire or along a long axis of arm of a branched nanocrystal. Different regions within a heterostructure can comprise entirely different materials, or the different regions can comprise a base material.

As used herein, a “nanostructure” is a structure having at least one region or characteristic dimension with a dimension of less than about 500 nm, e.g., less than about 200 nm, less than about 100 nm, less than about 50 nm, or even less than about 20 nm. Typically, the region or characteristic dimension will be along the smallest axis of the structure. Examples of such structures include nanowires, nanorods, nanotubes, branched nanocrystals, nanotetrapods, tripods, bipods, nanocrystals, nanodots, quantum dots, nanoparticles, branched tetrapods (e.g., inorganic dendrimers), and the like. Nanostructures can be substantially homogeneous in material properties, or in certain embodiments can be heterogeneous (e.g. heterostructures). Nanostructures can be, e.g., substantially crystalline, substantially monocrystalline, polycrystalline, amorphous, or a combination thereof. In one aspect, each of the three dimensions of the nanostructure has a dimension of less than about 500 nm, e.g., less than about 200 nm, less than about 100 nm, less than about 50 nm, or even less than about 20 nm.

As used herein, the term “nanowire” generally refers to any elongated conductive or semiconductive material (or other material described herein) that includes at least one cross sectional dimension that is less than 500 nm, and preferably, less than 100 nm, and has an aspect ratio (length:width) of greater than 10, preferably greater than 50, and more preferably, greater than 100.

The nanowires of this invention can be substantially homogeneous in material properties, or in certain embodiments can be heterogeneous (e.g. nanowire heterostructures). The nanowires can be fabricated from essentially any convenient material or materials, and can be, e.g., substantially crystalline, substantially monocrystalline, polycrystalline, or amorphous. Nanowires can have a variable diameter or can have a substantially uniform diameter, that is, a diameter that shows a variance less than about 20% (e.g., less than about 10%, less than about 5%, or less than about 1%) over the region of greatest variability and over a linear dimension of at least 5 nm (e.g., at least 10 nm, at least 20 nm, or at least 50 nm). Typically the diameter is evaluated away from the ends of the nanowire (e.g. over the central 20%, 40%, 50%, or 80% of the nanowire). A nanowire can be straight or can be e.g. curved or bent, over the entire length of its long axis or a portion thereof. In certain embodiments, a nanowire or a portion thereof can exhibit two- or three-dimensional quantum confinement. Nanowires according to this invention can expressly exclude carbon nanotubes, and, in certain embodiments, exclude “whiskers” or “nanowhiskers”, particularly whiskers having a diameter greater than 100 nm, or greater than about 200 nm.

Examples of such nanowires include semiconductor nanowires as described in Published International Patent Application Nos. WO 02/17362, WO 02/48701, and WO 01/03208, carbon nanotubes, and other elongated conductive or semiconductive structures of like dimensions, which are incorporated herein by reference.

As used herein, the term “nanorod” generally refers to any elongated conductive or semiconductive material (or other material described herein) similar to a nanowire, but having an aspect ratio (length:width) less than that of a nanowire. Note that two or more nanorods can be coupled together along their longitudinal axis so that the coupled nanorods span all the way between electrodes. Alternatively, two or more nanorods can be substantially aligned along their longitudinal axis, but not coupled together, such that a small gap exists between the ends of the two or more nanorods. In this case, electrons can flow from one nanorod to another by hopping from one nanorod to another to traverse the small gap. The two or more nanorods can be substantially aligned, such that they form a path by which electrons can travel between electrodes.

A wide range of types of materials for nanowires, nanorods, nanotubes and nanoribbons can be used, including semiconductor material selected from, e.g., Si, Ge, Sn, Se, Te, B, C (including diamond), P, B—C, B—P(BP6), B—Si, Si—C, Si—Ge, Si—Sn and Ge—Sn, SiC, BN/BP/BAs, AlN/AlP/AlAs/AlSb, GaN/GaP/GaAs/GaSb, InN/InP/InAs/InSb, BN/BP/BAs, AlN/AlP/AlAs/AlSb, GaN/GaP/GaAs/GaSb, InN/InP/InAs/InSb, ZnO/ZnS/ZnSe/ZnTe, CdS/CdSe/CdTe, HgS/HgSe/HgTe, BeS/BeSe/BeTe/MgS/MgSe, GeS, GeSe, GeTe, SnS, SnSe, SnTe, PbO, PbS, PbSe, PbTe, CuF, CuCl, CuBr, CuI, AgF, AgCl, AgBr, AgI, BeSiN2, CaCN2, ZnGeP2, CdSnAs2, ZnSnSb2, CuGeP3, CuSi2P3, (Cu, Ag)(Al, Ga, In, Tl, Fe)(S, Se, Te) 2, Si3N4, Ge3N4, Al2O3, (Al, Ga, In) 2 (S, Se, Te) 3, Al2CO, and an appropriate combination of two or more such semiconductors.

The nanowires can also be formed from other materials such as metals such as gold, nickel, palladium, iradium, cobalt, chromium, aluminum, titanium, tin and the like, metal alloys, polymers, conductive polymers, ceramics, and/or combinations thereof. Other now known or later developed conducting or semiconductor materials can be employed.

In certain aspects, the semiconductor may comprise a dopant from a group consisting of: a p-type dopant from Group III of the periodic table; an n-type dopant from Group V of the periodic table; a p-type dopant selected from a group consisting of: B, Al and In; an n-type dopant selected from a group consisting of: P, As and Sb; a p-type dopant from Group II of the periodic table; a p-type dopant selected from a group consisting of: Mg, Zn, Cd and Hg; a p-type dopant from Group IV of the periodic table; a p-type dopant selected from a group consisting of: C and Si; or an n-type dopant selected from a group consisting of: Si, Ge, Sn, S, Se and Te. Other now known or later developed dopant materials can be employed.

Additionally, the nanowires or nanoribbons can include carbon nanotubes, or nanotubes formed of conductive or semiconductive organic polymer materials, (e.g., pentacene, and transition metal oxides).

Hence, although the term “nanowire” is referred to throughout the description herein for illustrative purposes, it is intended that the description herein also encompass the use of nanotubes (e.g., nanowire-like structures having a hollow tube formed axially therethrough). Nanotubes can be formed in combinations/thin films of nanotubes as is described herein for nanowires, alone or in combination with nanowires, to provide the properties and advantages described herein.

It should be understood that the spatial descriptions (e.g., “above”, “below”, “up”, “down”, “top”, “bottom”, etc.) made herein are for purposes of illustration only, and that devices of the present invention can be spatially arranged in any orientation or manner.

There are many advantages of nanowires compared to standard semiconductors, including the use of insulating, flexible, or low-loss substrates, cost, and the ability to integrate nanowires into large structures. The present invention is directed to methods which apply these advantages to artificial dielectrics using nanowires. While the examples and discussion provided focus on nanowires, nanotubes, nanorods, and nanoribbons can also be used.

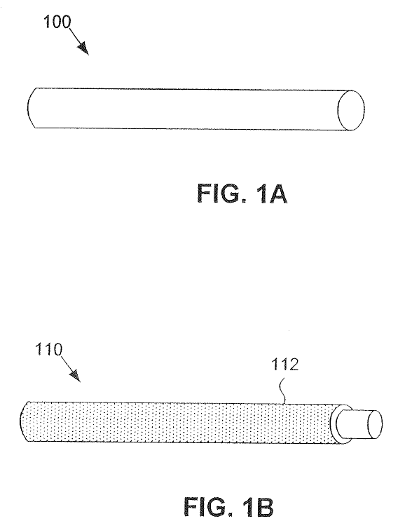

FIG. 1A illustrates a single crystal semiconductor nanowire core (hereafter “nanowire”) 100. FIG. 1A shows a nanowire 100 that is a uniformly doped single crystal nanowire. Such single crystal nanowires can be doped into either p- or n-type semiconductors in a fairly controlled way. Doped nanowires such as nanowire 100 exhibit improved electronic properties. For instance, such nanowires can be doped to have carrier mobility levels comparable to bulk single crystal materials.

FIG. 1B shows a nanowire 110 doped according to a core-shell structure. As shown in FIG. 1B, nanowire 110 has a doped surface layer 112, which can have varying thickness levels, including being only a molecular monolayer on the surface of nanowire 110.

The valence band of the insulating shell can be lower than the valence band of the core for p-type doped wires, or the conduction band of the shell can be higher than the core for n-type doped wires. Generally, the core nanostructure can be made from any metallic or semiconductor material, and the shell can be made from the same or a different material. For example, the first core material can comprise a first semiconductor selected from the group consisting of: a Group II-VI semiconductor, a Group III-V semiconductor, a Group IV semiconductor, and an alloy thereof. Similarly, the second material of the shell can comprise a second semiconductor, the same as or different from the first semiconductor, e.g., selected from the group consisting of: a Group II-VI semiconductor, a Group III-V semiconductor, a Group IV semiconductor, and an alloy thereof. Example semiconductors include, but are not limited to, CdSe, CdTe, InP, InAs, CdS, ZnS, ZnSe, ZnTe, HgTe, GaN, GaP, GaAs, GaSb, InSb, Si, Ge, AlAs, AlSb, PbSe, PbS, and PbTe. As noted above, metallic materials such as gold, chromium, tin, nickel, aluminum etc. and alloys thereof can be used as the core material, and the metallic core can be overcoated with an appropriate shell material such as silicon dioxide or other insulating materials

Nanostructures can be fabricated and their size can be controlled by any of a number of convenient methods that can be adapted to different materials. For example, synthesis of nanocrystals of various composition is described in, e.g., Peng et al. (2000) “Shape Control of CdSe Nanocrystals” Nature 404, 59-61; Puntes et al. (2001) “Colloidal nanocrystal shape and size control: The case of cobalt” Science 291, 2115-2117; U.S. Pat. No. 6,306,736 to Alivisatos et al. (Oct. 23, 2001) entitled “Process for forming shaped group III-V semiconductor nanocrystals, and product formed using process”; U.S. Pat. No. 6,225,198 to Alivisatos et al. (May 1, 2001) entitled “Process for forming shaped group II-VI semiconductor nanocrystals, and product formed using process”; U.S. Pat. No. 5,505,928 to Alivisatos et al. (Apr. 9, 1996) entitled “Preparation of III-V semiconductor nanocrystals”; U.S. Pat. No. 5,751,018 to Alivisatos et al. (May 12, 1998) entitled “Semiconductor nanocrystals covalently bound to solid inorganic surfaces using self-assembled monolayers”; U.S. Pat. No. 6,048,616 to Gallagher et al. (Apr. 11, 2000) entitled “Encapsulated quantum sized doped semiconductor particles and method of manufacturing same”; and U.S. Pat. No. 5,990,479 to Weiss et al. (Nov. 23, 1999) entitled “Organo luminescent semiconductor nanocrystal probes for biological applications and process for making and using such probes.”

Growth of nanowires having various aspect ratios, including nanowires with controlled diameters, is described in, e.g., Gudiksen et al (2000) “Diameter-selective synthesis of semiconductor nanowires” J. Am. Chem. Soc. 122, 8801-8802; Cui et al. (2001) “Diameter-controlled synthesis of single-crystal silicon nanowires” Appl. Phys. Lett. 78, 2214-2216; Gudiksen et al. (2001) “Synthetic control of the diameter and length of single crystal semiconductor nanowires” J. Phys. Chem. B 105,4062-4064; Morales et al. (1998) “A laser ablation method for the synthesis of crystalline semiconductor nanowires” Science 279, 208-211; Duan et al. (2000) “General synthesis of compound semiconductor nanowires” Adv. Mater. 12, 298-302; Cui et al. (2000) “Doping and electrical transport in silicon nanowires” J. Phys. Chem. B 104, 5213-5216; Peng et al. (2000) “Shape control of CdSe nanocrystals” Nature 404, 59-61; Puntes et al. (2001) “Colloidal nanocrystal shape and size control: The case of cobalt” Science 291, 2115-2117; U.S. Pat. No. 6,306,736 to Alivisatos et al. (Oct. 23, 2001) entitled “Process for forming shaped group III-V semiconductor nanocrystals, and product formed using process”; U.S. Pat. No. 6,225,198 to Alivisatos et al. (May 1, 2001) entitled “Process for forming shaped group II-VI semiconductor nanocrystals, and product formed using process”; U.S. Pat. No. 6,036,774 to Lieber et al. (Mar. 14, 2000) entitled “Method of producing metal oxide nanorods”; U.S. Pat. No. 5,897,945 to Lieber et al. (Apr. 27, 1999) entitled “Metal oxide nanorods”; U.S. Pat. No. 5,997,832 to Lieber et al. (Dec. 7, 1999) “Preparation of carbide nanorods”; Urbau et al. (2002) “Synthesis of single-crystalline perovskite nanowires composed of barium titanate and strontium titanate” J. Am. Chem. Soc., 124, 1186; and Yun et al. (2002) “Ferroelectric Properties of Individual Barium Titanate Nanowires Investigated by Scanned Probe Microscopy” Nanoletters 2, 447.

Growth of branched nanowires (e.g., nanotetrapods, tripods, bipods, and branched tetrapods) is described in, e.g., Jun et al. (2001) “Controlled synthesis of multi-armed CdS nanorod architectures using monosurfactant system” J. Am. Chem. Soc. 123, 5150-5151; and Manna et al. (2000) “Synthesis of Soluble and Processable Rod-, Arrow-, Teardrop-, and Tetrapod-Shaped CdSe Nanocrystals” J. Am. Chem. Soc. 122, 12700-12706.

Synthesis of nanoparticles is described in, e.g., U.S. Pat. No. 5,690,807 to Clark Jr. et al. (Nov. 25, 1997) entitled “Method for producing semiconductor particles”; U.S. Pat. No. 6,136,156 to El-Shall, et al. (Oct. 24, 2000) entitled “Nanoparticles of silicon oxide alloys”; U.S. Pat. No. 6,413,489 to Ying et al. (Jul. 2, 2002) entitled “Synthesis of nanometer-sized particles by reverse micelle mediated techniques”; and Liu et al. (2001) “Sol-Gel Synthesis of Free-Standing Ferroelectric Lead Zirconate Titanate Nanoparticles” J. Am. Chem. Soc. 123, 4344. Synthesis of nanoparticles is also described in the above citations for growth of nanocrystals, nanowires, and branched nanowires, where the resulting nanostructures have an aspect ratio less than about 1.5.

Synthesis of core-shell nanostructure heterostructures, namely nanocrystal and nanowire (e.g., nanorod) core-shell heterostructures, are described in, e.g., Peng et al. (1997) “Epitaxial growth of highly luminescent CdSe/CdS core/shell nanocrystals with photostability and electronic accessibility” J. Am. Chem. Soc. 119, 7019-7029; Dabbousi et al. (1997) “(CdSe)ZnS core-shell quantum dots: Synthesis and characterization of a size series of highly luminescent nanocrysallites” J. Phys. Chem. B 101, 9463-9475; Manna et al. (2002) “Epitaxial growth and photochemical annealing of graded CdS/ZnS shells on colloidal CdSe nanorods” J. Am. Chem. Soc. 124, 7136-7145; and Cao et al. (2000) “Growth and properties of semiconductor core/shell nanocrystals with InAs cores” J. Am. Chem. Soc. 122, 9692-9702. Similar approaches can be applied to growth of other core-shell nanostructures.

Growth of nanowire heterostructures in which the different materials are distributed at different locations along the long axis of the nanowire is described in, e.g., Gudiksen et al. (2002) “Growth of nanowire superlattice structures for nanoscale photonics and electronics” Nature 415, 617-620; Bjork et al. (2002) “One-dimensional steeplechase for electrons realized” Nano Letters 2, 86-90; Wu et al. (2002) “Block-by-block growth of single-crystalline Si/SiGe superlattice nanowires” Nano Letters 2, 83-86; and U.S. patent application Ser. No. 60/370,095 (Apr. 2, 2002) to Empedocles entitled “Nanowire heterostructures for encoding information.” Similar approaches can be applied to growth of other heterostructures.

In certain embodiments, the collection or population of nanostructures employed in the artificial dielectric is substantially monodisperse in size and/or shape. See, e.g., US patent application 20020071952 by Bawendi et al entitled “Preparation of nanocrystallites.”

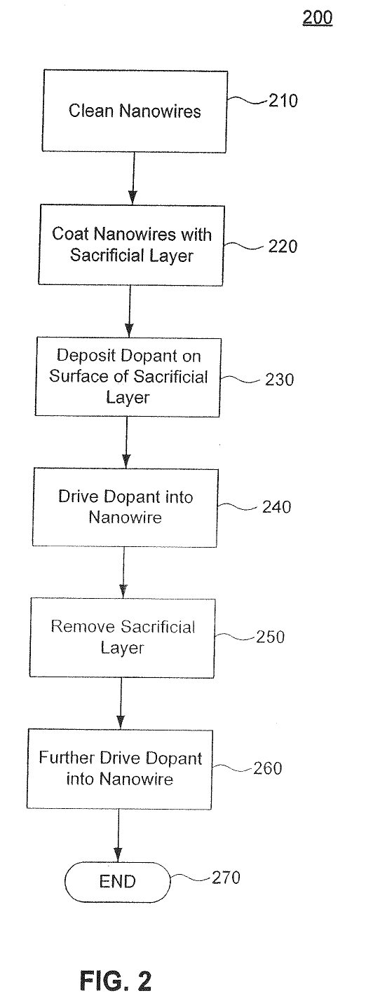

FIG. 2 is a flowchart of method 200 for doping nanostructures, according to an embodiment of the invention. Method 200 provides a method to dope a nanostructure such as, for example, a nanowire, with uniform, conformal and controllable doping concentrations. Method 200 takes advantage of the uniform and conformal doping properties of thermal diffusion. A sacrificial layer acts as a diffusion limiting factor, such that the doping level can be readily controlled.

Method 200 begins in step 210. In step 210, nanowires that are to be doped are cleaned. In an embodiment, an HF vapor is used to remove native oxides remaining on the nanowires. This cleaning can be done at room temperature, or at elevated temperatures with different ambient temperatures. Additionally, as an option additional cleaning can be done to remove organics. These cleaning methods can use, for example, O₂ plasma, IPA vapor or acetone vapor.

In step 220 the nanowires are coated with a sacrificial layer. An oxidation process, as will be known by individuals skilled in the relevant arts, can be used to form a sacrificial layer around the nanowires. For example, in the case of Si nanowires, a SiO₂ sacrificial layer can be formed. By using a sacrificial layer, such as SiO₂, the diffusivity of a dopant can be reduced such that a doping profile in nanowires can be tailored for a desired application. For example, by varying the sacrificial layer thickness and composition the dopant profile can be controlled within the nanowire. Other sacrificial layers can include, but are not limited to, SiNₓ, Al₂O₃, AlN, and WN.

In step 230 a dopant is deposited on the surface of the sacrificial layer. Thermal pre-deposition, as will be known by individuals skilled in the relevant arts, can be used to deposit the dopant onto the surface of the sacrificial layer. The process can be done in a furnace, for example. The sources for the dopant can be a gas, liquid or solid. Due to the density differences between the nanowire and sacrificial layer, the dopant will collect at the interface between the nanowire and the sacrificial layer, which can be referred to as a dopant segregation effect. The dopant segregation effect permits control of the dopant concentration at the surface of the nanowire by changing the sacrificial layer composition (i.e., changing the segregation factor) or modifying the process conditions.

In step 240 a pre-diffusion process is used to drive the dopant into the nanowires through the sacrificial layers. The temperature and time for the pre-diffusion process can be varied to determine the dopant profiles in both the sacrificial layers and the nanowires. Because thermal control is critical to achieve the desirable dopant profile, a rapid thermal annealing process will be the preferred approach. In other embodiments fast ramping rate annealing for dopant diffusion can be used. Fast ramping rate annealing processes can include, but are not limited to, laser annealing, flash lamp (arc) annealing, and plasma fusion annealing. These processes will be known to individuals skilled in the relevant arts. The benefits of using fast ramping rate annealing are that a low thermal budget is required and precise dopant profile control can be achieved, which are important for nanostructure doping applications.

In step 250 the sacrificial layer is removed. An etch can be used to strip off the sacrificial layer. When using a SiO₂ sacrificial layer, a vapor HF etch can be used. Upon removing the sacrificial layer, only the nanowires with controlled doping concentrations will remain.

In step 260 the dopant is further driven into the nanowires, depending on the desired application. A final thermal annealing process drives the dopant into the nanowires to further achieve the desirable dopant distribution (i.e., dopant profile) and activation. This final dopant drive step can be done alone, or it can be integrated into subsequent thermal processes, such as, for example, gate oxidation of the nanowires. Both thermal furnace-based and rapid thermal annealing can be used for this step. In other embodiments fast ramping rate annealing for dopant diffusion can be used. Fast ramping rate annealing processes can include, but are not limited to, laser annealing, flash lamp (arc) annealing, and plasma fusion annealing. These processes will be known to individuals skilled in the relevant arts. In step 270, method 200 ends.

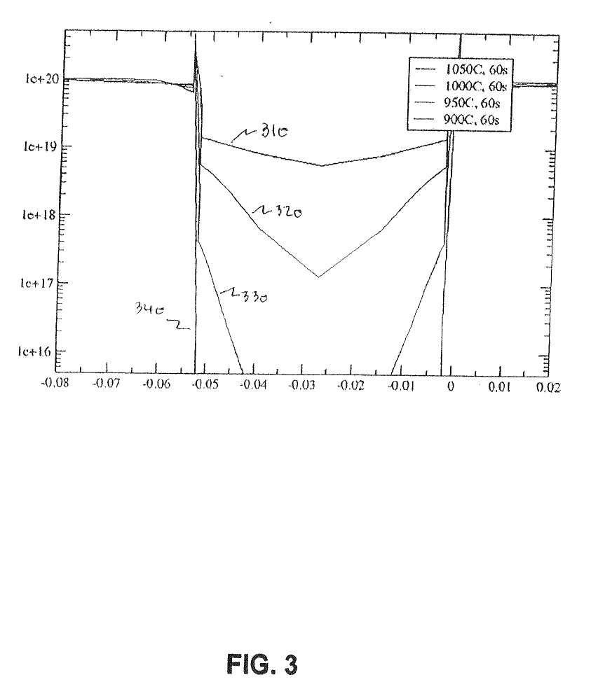

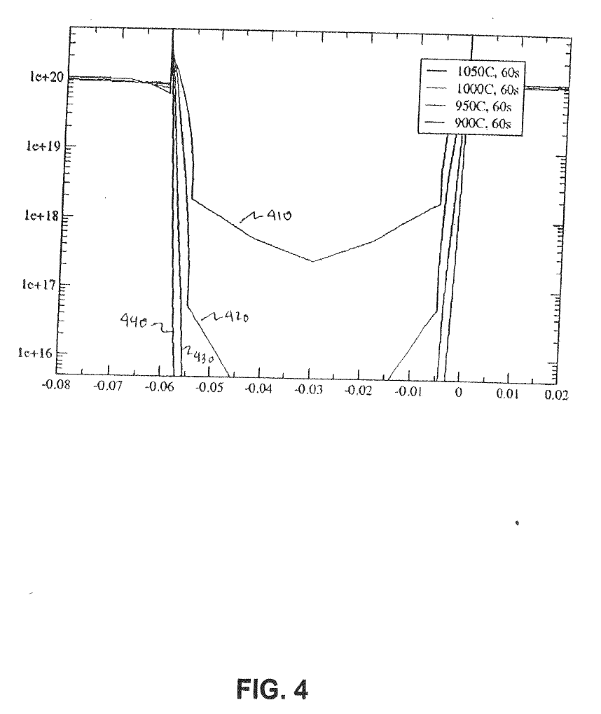

FIG. 3 provides a chart of doping concentrations in nanowires with a 2 nm SiO₂ sacrificial layer under different pre-diffusion conditions, according to an embodiment of the invention. FIG. 4 provides a chart of doping concentrations in nanowires with a 2 nm SiO₂ sacrificial layer under different pre-diffusion conditions, according to an embodiment of the invention. In each of the charts, the vertical axis shows doping concentration levels and the horizontal axis shows the depth of the measurement within the silicon nanowire.

Referring to FIG. 3 line 310 represents the case in which a temperature of 1050° C. is used to drive the dopant into the nanowires for 60 seconds during the pre-diffusion step 240. Line 320 represents the case in which a temperature of 1000° C. is used to drive the dopant into the nanowires for 60 seconds during the pre-diffusion step 240. Line 330 represents the case in which a temperature of 950° C. is used to drive the dopant into the nanowires for 60 seconds during the pre-diffusion step 240. Line 340 represents the case in which a temperature of 900° C. is used to drive the dopant into the nanowires for 60 seconds during the pre-diffusion step 240.

Referring to FIG. 4, line 410 represents the case in which a temperature of 1050° C. is used to drive the dopant into the nanowires for 60 seconds during the pre-diffusion step 240. Line 420 represents the case in which a temperature of 1000° C. is used to drive the dopant into the nanowires for 60 seconds during the pre-diffusion step 240. Line 430 represents the case in which a temperature of 950° C. is used to drive the dopant into the nanowires for 60 seconds during the pre-diffusion step 240. Line 440 represents the case in which a temperature of 900° C. is used to drive the dopant into the nanowires for 60 seconds during the pre-diffusion step 240.

The charts in FIGS. 3 and 4 illustrate that doping concentrations both at the surface and inside the nanowires can be controlled even at low doping levels, such as 10¹⁸/cm³.

### Ion Implantation for Doping

Another approach to doping nanostructures involves the use of an ion implanter. Current low temperature implants can amorphize the nanowires. Thus, the range and angles must be controlled so as to leave an undoped region that the crystal can regrow from. Also, there is a dose range below which amorphization takes place where it is difficult to regrow good single crystal silicon. It is difficult to uniformly dope a random tangle of wires on the growth wafer using existing approaches while at the same time keeping a portion of the cross-section of each wire undamaged.

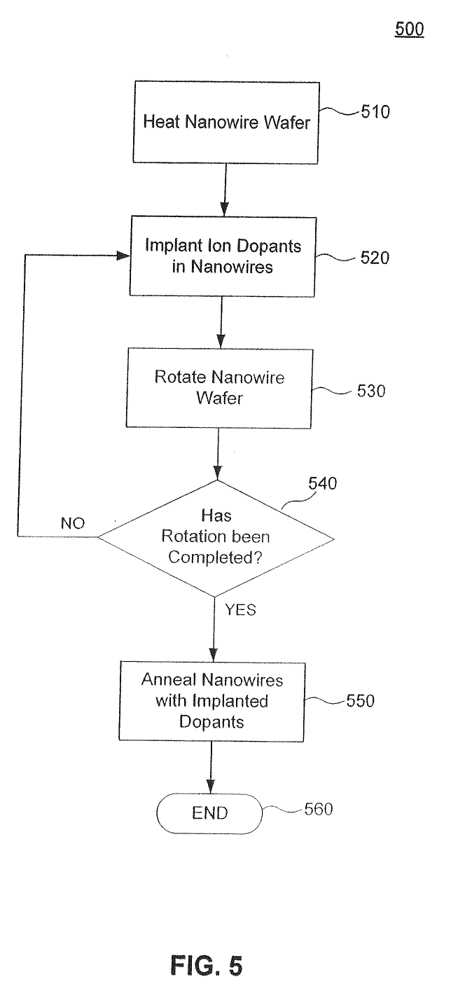

An embodiment of the invention addresses the shortcomings of existing ion implanter approaches to doping nanowires. FIG. 5 provides method 500 for doping nanostructures using a high energy ion implanter, according to an embodiment of the invention. Method 500 begins in step 510.

In step 510 a growth wafer containing nanowires in heated to a sufficient temperature such that damage caused by ion implantation is annealed out during the implantation. In other embodiments, other types of nanostructures can be used, such as, for example, nanotubes and nanorods. Example temperatures can range from about 100 to 200° C. The preferred temperature will be a function of the type of nanowire material, the type of doping material, and the energy level of the ion implanter. Individuals skilled in the art will be able to determine the preferred temperature based on their application and the teachings herein.

In step 520 ion dopants are implanted into the nanowires. The implantation can be done at various angles on a rotating wafer. This allows doping to occur from many angles and minimizes shadowing effects.

In optional step 530 the nanowire wafer is rotated. Ion implantation can occur while the wafer is being rotated, or ion implantation can occur while the nanowire wafer is stationary following a rotation. The rotation can involve rotation about both a vertical and horizontal axis relative to the wafer. In step 540 a determination is made whether rotation has been completed. If the rotation process has not been completed, method 500 returns to step 520 for additional dopant ions to be implanted. If the rotation process has been completed, method 500 proceeds to step 550.

In step 550 the nanowires with the implanted dopants are annealed. The annealing activates the dopant and helps to distribute the dopant uniformally throughout the nanowire, while also minimizing shadowing. In an embodiment the anneal step can be combination with the oxidation step that grows the shell (gate) oxide on the nanowire, so that an additional growth process step is not needed.

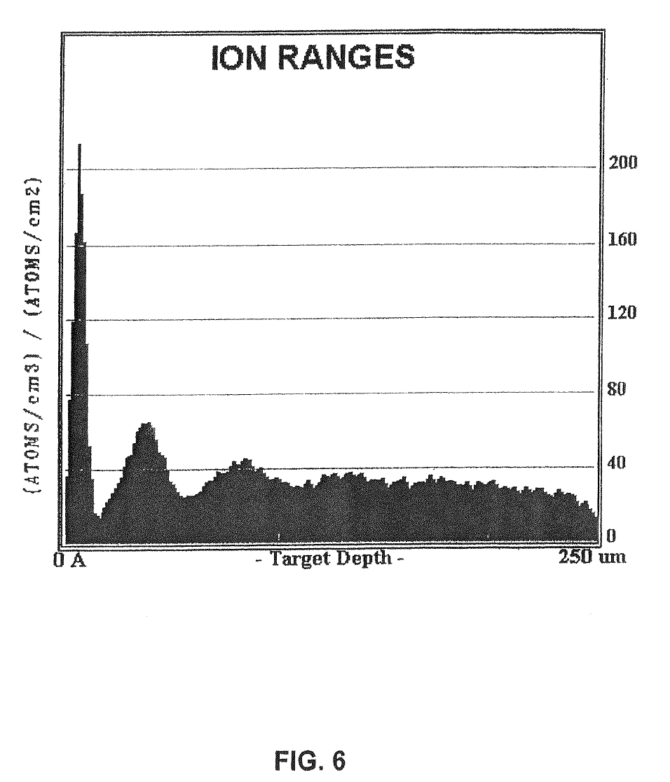

FIG. 6 provides a simulation chart showing boron dopant distribution into Silicon nanowires using method 500. In this example, the ion type is Boron and the nanowire material is Silicon. The ion energy was 10 keV. The chart illustrates a relatively constant density of ion implantation across a target depth within the Silicon nanowire ranging from 0 to 250 μm. With the optimization of ion energies and dose a nearly uniform doping density versus depth can be achieved.

### Diffusion Doping Involving Sacrificial Barrier Layers

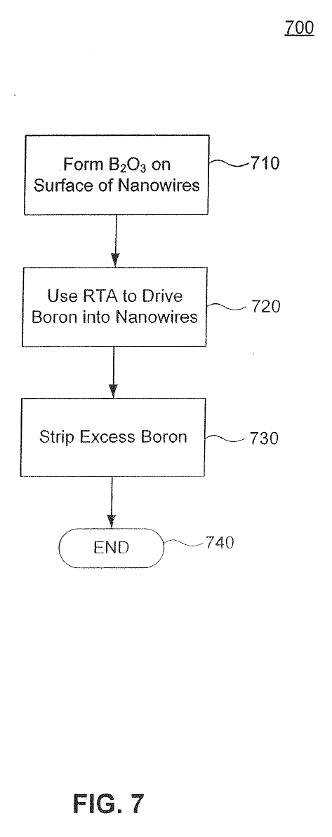

FIG. 7 provides a flowchart of method 700 for controlled doping of nanowires post nanowire synthesis, according to an embodiment of the invention.

Method 700 begins in step 710. In step 710 a dopant layer is formed on the surface of nanowires. In other embodiments, other types of nanostructures can be used, including, but not limited to nanotubes and nanorods. For example, in the case of p-doping of silicon nanowires using boron, a dopant layer of B₂O₃ is formed on the surface of the nanowires. The B₂O₃ dopant layer can be formed by using diborane and oxygen at temperatures above the decomposition temperature of diborane (e.g., approximately 350° Celsius). Process parameters within a chemical vapor deposition (“CVD”) furnace can be used to control B₂O₃ formation. The process parameters include total pressure, constituent partial pressure, flowrate, temperature and time. In other embodiments, other precursors can also be used including BF₃, decaborane and B₂O₃. In other embodiments other types of p-type dopants and nanostructure materials can be used. Additionally, n-type dopants using, for example, phosphorus precursors can be used in other embodiments.

Other methods for nanostructure doping including ion implantation, as discussed with respect to FIG. 5. Also, plasma enhanced shower systems can be employed allowing for lower temperature boron precursor decomposition. Biases within a plasma reactor can be used to drive the dopant into the nanostructure.

In step 720 rapid thermal annealing (“RTA”) is used to drive boron into the nanowires to achieve the desired doping level. RTA Process parameters such as time and temperature are varied to drive in and activate the dopant. In an alternate embodiment a sacrificial barrier layer can be applied to the nanowires in order to not excessively dope the nanowires.

In step 730 excess Boron is stripped from the nanowires. Methods to strip the excess Boron will be known to individuals skilled in the relevant arts. In step 740, method 700 ends.

### Dielectric Mirrors to Minimize Damage to Plastic Substrates During Laser Anneal Activation of Dopants in Nanostructures on Plastic Substrates

In some methods for doping nanostructures, dopants are activated in nanostructures by a ten second anneal at 900° Celsius. This temperature is too high for nanowire devices that are grown on plastic substrates. Laser annealing of the dopants has been proposed as a possible technique for dopant activation and is currently used in the semiconductor industry. However, use of laser annealing still presents a challenge in that absorption of the laser energy into the plastic substrate can heat and destroy the plastic substrate.

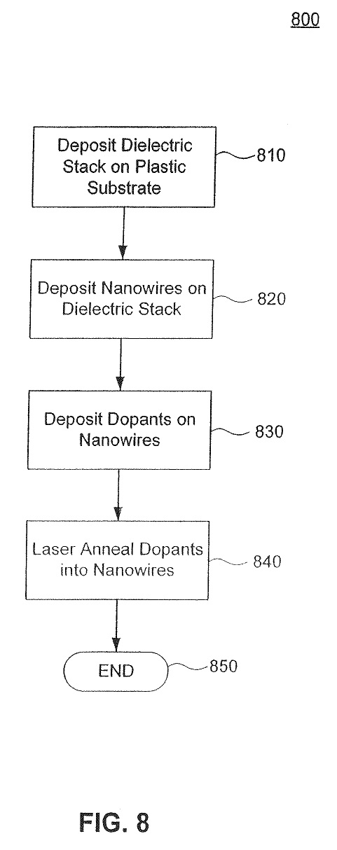

FIG. 8 provides a flowchart of method 800 for doping nanostructures on plastic substrates without damaging the plastic substrate, according to an embodiment of the invention. Method 800 begins in step 810.

In step 810 a dielectric stack is deposited on a plastic substrate. The dielectric stacks can include SiN, SiO₂, Al₂O₃, or AlON, for example. The dielectric stacks are deposited at low temperature, for example, using plasma enhanced chemical vapor deposition (“PECVD”) prior to deposition of nanowires on the plastic substrate. The thickness and number of layers of the dielectric stacks can be adjusted based on the laser wavelength to be used for laser annealing. Other low temperature deposition methods, as will be known by individuals skilled in the relevant arts based on the teachings herein can be used to deposit the dielectric stack.

In step 820 nanowires are deposited on the dielectric stack. Methods for depositing nanowires on the dielectric stack will be known to individuals skilled in the relevant arts based on the teachings herein. In other embodiments other nanostructures, such as, for example, nanotubes and nanorods can be used. In step 830 dopant materials are deposited on the nanowires. Methods for depositing dopants on the nanowires will be known to individuals skilled in the relevant arts based on the teachings herein.

In step 840 the dopant materials are laser annealed into the nanowires. The dielectric stack deposited in step 810 serves as a dielectric mirror to reflect laser energy and protects the plastic substrate from overheating, and corresponding degradation. In step 850, method 800 ends.

### Method for Doping Nanostructures for Higher Strength and Better Electrical Contact

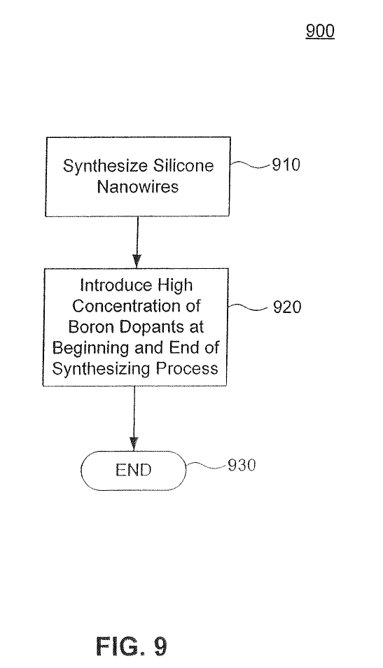

Doping nanostructures during nanostructure growth is a difficult challenge. FIG. 9 provides a flowchart of method 900 for doping nanowires to create a novel structure that provides higher strength and better electrical contact, according to an embodiment of the invention. A novel single crystal silicon using boron has been identified by Japanese researchers that led to an alternating twin structure grown on <111> silicon substrates. No line defects (scattering centers) are created at these twin boundaries. This twinned structure is then combined with an un-twinned structure to form a silicon hetero-structural device without creating an interface dislocation.

The present invention provides a method to create another novel structure of silicon doped with boron. FIG. 9 provides a flowchart of method 900 for creating a novel structure of silicon doped with boron, according to an embodiment of the invention. Method 900 begins in step 910. In step 910 silicon nanowires are synthesized.

During step 910, in step 920 high concentrations of boron dopants are introduced at the beginning and end of synthesizing step 910. High concentrations of boron dopants can also be introduced throughout the synthesize process to increase the strength of the nanowires. For example, 10% BCl₃ can be introduced with SiCl₄ during nanowire growth. Boron ordering in silicon nanowires is found at high doping concentrations on crystallographic planes parallel to the nanowire growth direction. Ordering has been observed on crystallographic planes parallel to the nanowire growth direction. Both <211> and <111> growth directions have been observed. The ordering was detected by diffraction patterns that describe the orientation with respect to nanowire growth. Images of the nanowires show no defects present in the nanowires such as dislocations or stacking faults. Ordering occurs in materials to relieve local strain without forming dislocations. The ordered nanowire is in a higher compressive strain than without boron. Ordering in materials increases the yield strength and therefore can be useful for silicon nanowires where higher strength is required.

Additionally, electrical measurements showed the highly ordered nanowires to be electrically degenerate. Thus, high concentrations of boron at the beginning and end of nanowire growth can be applied as a way of doping nanowires for better electrical contacts.

In embodiments, other dopants, such as Zn, for example, can be used. Additionally, the silicon source for synthesis includes, but is not limited to SiCl₄ and SiH₄.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A method of synthesizing a nanowire with electrical contacts, comprising:
(a) initiating nanowire growth, wherein a high concentration of dopants are introduced, wherein an end portion of the nanowire will exhibit metallic characteristics;
(b) reducing the concentration of dopants for a period of time, wherein a middle portion of the nanowire will exhibit semiconductor characteristics; and
(c) increasing the concentration of dopants near the end of the nanowire growth, wherein a second end portion of the nanowire will exhibit metallic characteristics.

2. The method of claim 1, wherein the nanowire comprises silicon and the dopant comprise boron.
